(19) United States
(12) Patent Application Publication
(10) Pub. No.: US 2008/0014664 A1
(43) Pub. Date: Jan. 17, 2008

(54) MANUFACTURING METHOD OF LIGHT EMITTING DIODE

(75) Inventors: Cheng-Yi Liu, Taoyuan (TW); Shih-Chieh Hsu, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NATIONAL CENTRAL UNIVERSITY, Taoyuan (TW)

(21) Appl. No.: 11/862,193

(22) Filed: Sep. 27, 2007

Related U.S. Application Data
(62) Division of application No. 11/164,133, filed on Nov. 11, 2005.

(30) Foreign Application Priority Data
May 12, 2005 (TW) 94115330

(51) Int. Cl. H01L 33/00

(52) U.S. Cl. 438/29; 257/E33.06

(57) ABSTRACT

A method for fabricating a light emitting diode (LED) is provided. A first-type doped semiconductor layer, a light emitting layer and a second-type doped semiconductor layer are formed on an epitaxy substrate sequentially. Then, a gold layer is formed on the second-type doped semiconductor layer. Next, a bonding substrate is provided. The bonding substrate includes a silicon substrate and a germanium-contained layer disposed on the silicon substrate. Then, a bonding process is performed on the bonding substrate and the gold layer. Next, the epitaxy substrate is removed. Accordingly, a LED with better reliability and light-emitting efficiency can be made. Moreover, a LED is also provided.

### CROSS-REFERENCE TO RELATED APPLICATION

This application is a divisional of an application Ser. No. 11/164,133, filed on Nov. 11, 2005, now pending, which claims the priority benefit of Taiwan application serial no. 94115330, filed on May 12, 2005. The entirety of each of the above-mentioned patent applications is hereby incorporated by reference herein and made a part of this specification.

### BACKGROUND OF THE INVENTION

1. Field of the Invention

This invention generally relates to a diode and a manufacturing method thereof, and especially to a light emitting diode (LED) and a manufacturing method thereof.

2. Description of Related Art

In recent years, light emitting diodes (LED), which contains semiconductor with GaN compound such as GaN, AlGaN and InGaN, have come to people's attention. The nitride of Group IIIA in the Periodic Table of the Elements is a material with broad energy bandgap, whose light emitting wave length ranges from ultraviolet to red or almost all visible wave bands. Besides, compared with traditional light bulb, the light emitting diode has absolute advantage, such as small volume, long lifespan, low voltage/current drive, break resistance, no mercury (no pollution problem) and high energy save, etc., therefore light emitting diode is widely utilized in the industry.

FIG. 1 is a cross- sectional view of a conventional GaN-based light emitting diode. As shown in FIG. 1, a conventional GaN-based light emitting diode 100 comprises a sapphire substrate 110, a doped semiconductor layer 122, a light emitting layer 124 and a doped semiconductor 126. Wherein, the doped semiconductor layer 122 is disposed on the sapphire substrate 110. Further, the light emitting layer 124 is disposed on a portion of the doped semiconductor layer 122, and the doped semiconductor 126 is disposed on the light emitting layer 124. Note that above-mentioned doped semiconductor layer 122 and the doped semiconductor layer 126 are different type of doped semiconductor layers. For example, when the doped semiconductor layer 122 is a N-type doped semiconductor layer, then the doped semiconductor layer 126 is an P-type doped semiconductor layer.

In details, bonding pads 132 and 134 can be respectively disposed on the doped semiconductor layer 126 and on the area of the doped semiconductor layer 122 not covered by the doped semiconductor layer 126. Further, the bonding-pads 132 and 134 generally are made of a metal material. Note that the conventional light emitting diode 100 is electrically connected to a circuit board or other carriers (not shown) by a wire bonding technology or flip chip technology, wherein the bonding-pads 132 and 134 are the connection nodes of the electrical connection.

In the above-mentioned conventional light emitting diode 100, because the heat dissipation of the sapphire substrate 100 is not satisfactory, usually the internal temperature increases gradually for long-time light emission, so the light emitting efficiency of the light emitting layer 124 correspondingly decreases gradually. Further, because of the current crowding effect near the bonding-pads 132 and 134 when driving, when the current is large, the bonding-pads 132 and 134, or the neighboring doped semiconductor layers 122 and 126 might be damaged, and the conventional light emitting 100 can not function normally.

Besides, another conventional light emitting diode is described with reference to FIG. 2.

FIG. 2 is a cross-sectional view of another conventional light emitting diode. As shown in FIG. 2, a conventional light emitting diode 200 comprises a conductive substrate 210, a doped semiconductor layer 222, a light emitting layer 224 and a doped semiconductor layer 226, wherein the doped semiconductor layer 222 is disposed on the conductive substrate 210. Further, the light emitting layer 224 is disposed between the doped semiconductor layer 222 and the doped semiconductor layer 226.

Similarly, a bonding-pad 232 is disposed on the doped semiconductor layer 226, wherein the function of the bonding-pad 232 is the same as the bonding-pad 132 as shown in FIG. 1. However, the conductive substrate 210 has conductive property, so that when the conventional light emitting diode 200 is disposed on the circuit board or other carriers, the conductive substrate 210 can be electrically connected with the circuit board directly, and electrically connected with the circuit board through a wire (not shown) disposed on the bonding-pad 232.

According to the above mentioned, the manufacturing method of the conventional light emitting diode 200 is, for example, by sequentially forming the doped semiconductor layer 226, the light emitting layer 224 and the doped semiconductor layer 222 on the sapphire substrate (not shown). Further, the doped semiconductor layer 222 and the conductive substrate 210 are bonded by a wafer bonding technology. Further, the sapphire substrate is removed by a laser lift-off process. At last, the bonding-pad 232 is formed, and the conventional light emitting diode 200 is formed.

The conventional technology of bonding the doped semiconductor layer 222 and the conductive substrate 210 is to apply Pd—In metal bonding. However, since the laser lift-off manufacturing process can generate a high temperature at about 1000° C., and the Pd—In intermetallic compound can not endure the high temperature, the bonding strength between the doped semiconductor layer 222 and the conductive substrate 210 is therefore decreased, and the reliability of the LED made is decreased.

### SUMMARY OF THE INVENTION

An object of the present invention is to provide a light emitting diode manufacturing method, for manufacturing a light emitting diode with higher thermal reliability bonding interface.

Another object of the present invention is to provide a light emitting diode with higher thermal reliability bonding interface.

In accordance with the above and other objects, the present invention provides a light emitting diode manufacturing method, comprising the following steps: First, a first-type doped semiconductor layer, a light emitting layer and a second-type doped semiconductor layer are formed on an epitaxy substrate sequentially. Then, a gold layer is formed on the second-type doped semiconductor layer. Next, a bonding substrate is provided. The bonding substrate comprises a silicon substrate and a germanium-contained layer disposed on the silicon substrate. Then, a bonding process is performed between the germanium-contained layer and the gold layer. Next, the epitaxy substrate is removed.

In accordance with the embodiments of the present invention, the germanium-contained material layer is a solid germanium material layer or a silicon germanium alloy layer.

In accordance with the embodiments of the present invention, the pressure applied in the bonding process is for example between 1 kg/cm2 to 100 kg/cm2.

In accordance with the embodiments of the present invention, the temperature applied in the bonding process is between 250° C. to 400° C.

In accordance with the embodiments of the present invention, the method of removing the epitaxy substrate for example is a laser lift-off process, wherein the laser lift-off process applies excimer laser.

In accordance with the embodiments of the present invention, before the bonding process, a cleaning process for the bonding substrate is performed.

In accordance with the embodiments of the present invention, before the first-type doped semiconductor layer is formed, a buffer layer is formed on the epitaxy substrate. Further, the buffer layer can be removed after the epitaxy substrate is removed.

In accordance with the embodiments of the present invention, before the gold layer is formed, an ohmic contact layer is formed on the second-type doped semiconductor layer. Further, a reflect layer is formed on the ohmic contact layer, for example, after the ohmic contact layer is formed.

In accordance with the embodiments of the present invention, after the epitaxy substrate is removed, a bonding-pad is formed on the first type doped semiconductor layer.

In accordance with the embodiments of the present invention, after the epitaxy substrate is removed, a part of the first-type doped semiconductor layer and the light emitting layer can be further removed, for exposing a part of the surface on the second-type doped semiconductor layer. Further, a first bonding-pad is formed on the first-type doped semiconductor layer. Furthermore, a second-type bonding-pad is formed on the second-type doped semiconductor layer not covered by the light emitting layer.

In accordance with the above and other objects, the present invention provides another light emitting diode, comprising a silicon substrate, a germanium-contained material layer, a gold layer and a semiconductor layer, wherein, the germanium-contained material layer is disposed on the silicon substrate, the gold layer is disposed on the germanium-contained layer, and the semiconductor layer is disposed on the gold layer. Further, the semiconductor layer comprises a first-type doped semiconductor layer, a light emitting layer and a second-type doped semiconductor layer, wherein, the first-type doped semiconductor layer is disposed on the gold layer, and the light emitting layer is disposed between the first-type doped semiconductor layer and the second-type doped semiconductor layer.

In accordance with the embodiments of the present invention, the germanium-contained material layer is, for example, a solid germanium material layer or a silicon germanium alloy layer.

In accordance with the embodiments of the present invention, the light emitting diode further comprises an ohmic contact layer which is disposed between the gold layer and the semiconductor layer. Besides, the light emitting diode further comprises a reflective layer disposed between the gold layer and the ohmic contact layer.

In accordance with the embodiments of the present invention, the thickness of the germanium-contained material layer is between 1 angstrom to 1 micron. Further, the thickness of the germanium-contained material layer is, for example, 50 angstrom.

In accordance with the embodiments of the present invention, the thickness of the gold layer is between 0.1 micron to 10 microns.

In accordance with the embodiments of the present invention, the first-type doped semiconductor layer is an N-type doped semiconductor layer, the second-type doped semiconductor layer is a P-type doped semiconductor layer. Or, the first-type doped semiconductor layer is a P-type doped semiconductor layer, and the second-type doped semiconductor layer is an N-type doped semiconductor layer.

In accordance with the embodiments of the present invention, the light emitting layer is, for example, a doped semiconductor layer comprising three or four elements.

According to the above mentioned, compared with the conventional technology, the present invention utilizes gold and germanium as the bonding material, and utilizes the gold-germanium-silicon ternary eutectic bond as the bonding function. The eutectic temperature is lower than a gold-silicon eutectic temperature, therefore the thermal stress remaining after the manufacturing process is lower, such that the interface bonding reliability of the light emitting diode of the present invention is better. Also, the light emitting efficiency of the light emitting diode of the present invention is better.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIG. 1 is a cross-sectional view of a conventional light emitting diode.

FIG. 2 is a cross-sectional view of another conventional light emitting diode.

FIGS. 3A to 3D are schematic views of a process of manufacturing a light emitting diode according to a first embodiment of the present invention.

FIG. 4 is a current-voltage curve chart of a light emitting diode according to a first embodiment of the present invention.

FIGS. 5A to 5B are schematic views of a process of manufacturing a light emitting diode according to a second embodiment of the present invention.

### DESCRIPTION OF THE EMBODIMENTS

### First embodiment

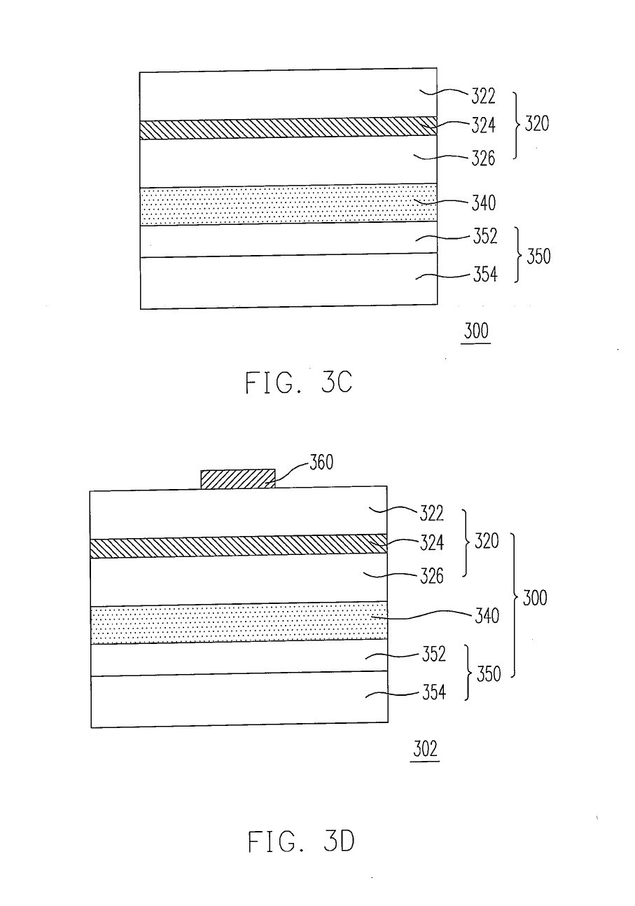

FIGS. 3A to 3D are cross-sectional views of a process of manufacturing a light emitting diode according to a first embodiment of the present invention. As shown in FIG. 3A, the manufacturing method of light emitting diode of the present invention comprises the following steps. First, an epitaxy substrate 310 is provided, then a doped semiconductor layer 322, a light emitting layer 324 and a doped semiconductor layer 326 are formed on the epitaxy substrate 310 in an epitaxy manner. Further, the material of the epitaxy substrate 310 is semiconductor or non-semiconductor material, such as Glass, GaAs, GaN, AlGaAs, GaP, SiC, InP, BN, Al2O3 or AlN, etc. Note that in order to improve the electricity characteristic of the doped semiconductor layer 322, a buffering layer 330 also can be formed on the epitaxy substrate 310, before the doped semiconductor layer 322 is formed.

As shown in FIG. 3B, further, a gold layer 340 is formed on the doped semiconductor layer 326, wherein the method of forming the gold layer 340 is, for example, electron gun vapor plating process, vapor plating process, sputtering process, physical vapor deposition process or other metal film process. Further, a bonding substrate 350 is provided, wherein the bonding substrate 350 comprises a silicon S substrate 354 and a germanium-contained layer 352. The germanium-contained layer 352 is disposed on the silicon substrate 354. The germanium-contained layer 352 is a solid germanium layer or other mixed material layer which at least contains germanium element.

Further, a bonding process is performed to the germanium-contained layer 352 and the gold layer 340. In details, the bonding process is performed on the gold layer 340, the germanium-contained layer 352 and the silicon substrate 354 to form the gold-germanium-silicon ternary eutectic bonding state. Because that the gold-germanium-silicon eutectic temperature is below 360° C., when the temperature of the bonding process is for example at 360° C., the gold-germanium-silicon eutectic bonding state can be formed. In other words, in the process that the temperature decreases from the gold-germanium-silicon eutectic temperature 360° C. to room temperature, the thermal remaining stress generated by the temperature variation is lower than the conventional thermal remaining stress induced by high temperature bonding process. Therefore, compared with the conventional light emitting diode which utilizes the silicon substrate as main transferring material, the accumulated stress of the light emitting diode of the present invention is relatively lower, and the semiconductor film layer is not easily broken after the laser lift-off process. Besides, when forming the gold-germanium-silicon eutectic bonding state, the crystal state is stable and the bonding strength is high. According to the above mentioned, the light emitting diode manufactured by the light emitting diode manufacturing process of the first embodiment of the present invention has better bonding interface.

Further, the preferred pressure applied in the bonding process is between 1 kg/cm2 to 100 kg/cm2, and the preferred temperature applied in the bonding process is between 300° C. to 400° C. However, it is to be understood that the pressure and temperature applied in the bonding process in the embodiment is not limited thereto. Further, note that, in order to improve the interface characteristic of the bonding substrate 350, a RCA cleaning process or other cleaning process on the bonding substrate can be performed before the bonding process.

As shown in FIG. 3C, after the bonding process, the epitaxy substrate 310 is removed, for finishing the manufacturing process of the light emitting diode 300. Further, the method of removing the epitaxy substrate 310 is, for example, laser lift-off process, wherein the laser lift-off process applies excimer laser, for example. For an instance, the laser lift-off process is applies KrF excimer laser with a wavelength of 248 nanometer. Furthermore, when the buffer layer 330 is formed on the epitaxy substrate 310, the buffer layer 330 can be further removed, after removing the epitaxy substrate 310.

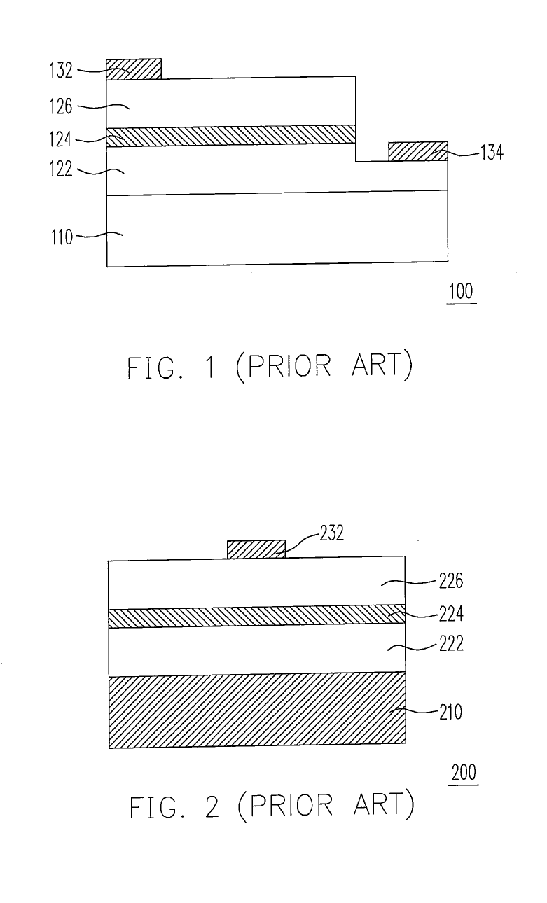

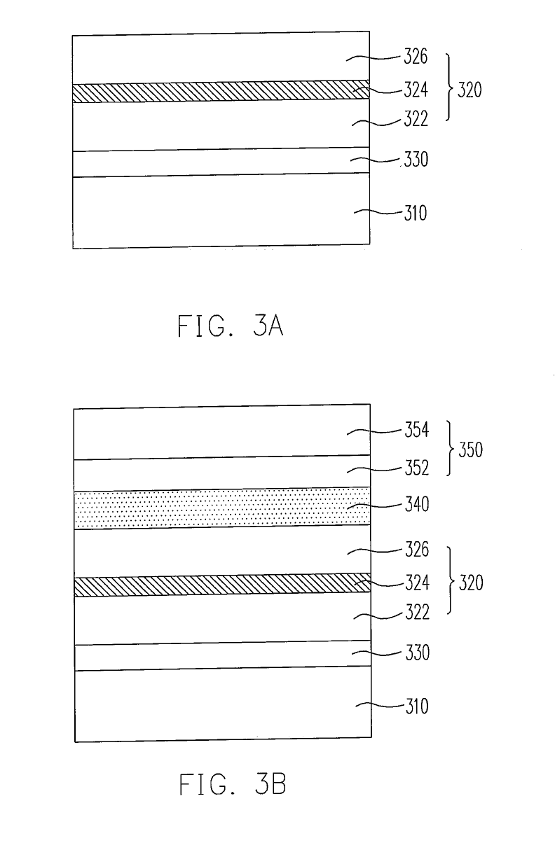

As shown in FIG. 3D, the structure formed by the above manufacturing process can be further utilized to manufacture a planar light emitting diode as shown in FIG. 1 or an upright light emitting diode as shown in FIG. 2. With respect to the upright light emitting diode manufacturing process, a bonding-pad 360 is formed on the doped semiconductor layer 322 after removing the epitaxy substrate 310, to finish the manufacturing process of the vertical light emitting diode 302. The bonding-pad 360 can serve as a connection node for the electrical connection to the circuit board or other carriers, through a conductive wire disposed on the bonding-pad 360 (not shown). Further, the structure of the light emitting diode 300 can be described as follows.

As shown in FIG. 3D, the light emitting diode 300 comprises a bonding substrate 350, a gold layer 340 and a semiconductor layer 320, wherein the gold layer 340 is disposed between the germanium-contained layer 352 and the doped semiconductor layer 326, and the thickness of the gold layer 340 is for example between 0.1 micron to 10 microns. Further, the bonding substrate 350 comprises a silicon substrate 354 and a germanium-contained layer 352. The germanium-contained layer 352 is disposed on the silicon substrate 354. The semiconductor layer 320 comprises the doped semiconductor layer 322, the doped semiconductor layer 326 and the light emitting layer 324 which is disposed between the doped semiconductor layers 322 and 326. Note that the upright light emitting diode 302 can be formed after a bonding-pad 360 is disposed on the light emitting diode 300.

When the doped semiconductor layer 322 is an N-type doped semiconductor layer, the doped semiconductor layer 326 is a P-type doped semiconductor layer. Or, the doped semiconductor layer 322 is a P-type doped semiconductor layer, and the doped semiconductor layer 326 is an N-type doped semiconductor layer. Further, the material of the light emitting layer 324 is, for example, multi-quantum well structure which are mainly Group III-V elements, and the light emitting layer 324 is a doped semiconductor with elements such as GaN, GaAs and AlN, or AlGaN and InGaN with three elements, or GaInAsN and GaInPN with four elements. Furthermore, the electricity characteristic of the light emitting diode 300 is described as follows.

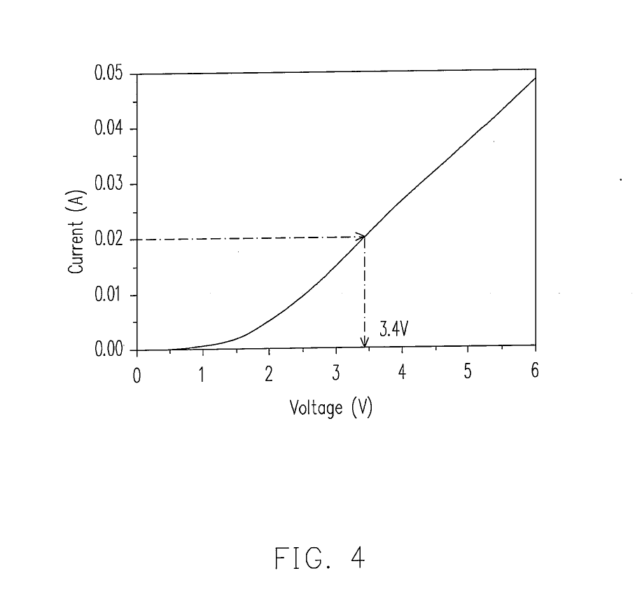

FIG. 4 is a current-voltage curve chart of a light emitting diode according to a first embodiment of the present invention. The horizontal coordinate is voltage (Volt), and the vertical coordinate is current (Ampere). As shown in FIG. 4, the forward voltage is 3.4 volts when the driving current is 20 mA, which is similar with the prior art value. In other words, the gold-germanium-silicon eutectic bond among the gold layer 340, the germanium-contained layer 352 and the silicon substrate 354 yields good electricity characteristic. Further, the light emitting diode 300 has better light emitting efficiency.

Compared with the conventional technology where Pd—In solder is utilized as the bonding material, the present invention utilizes gold-germanium-silicon as the bonding material. Because the gold-germanium-silicon ternary eutectic state is stable, a certain bonding strength between the gold layer 340 and the bonding substrate 350 can be maintained. Further, the gold-germanium-silicon eutectic temperature is lower than 360° C., therefore, during the high temperature laser lift-off process, the thermal stress caused by temperature variation can be decreased, so that the bonding strength between the gold layer 340 and the bonding substrate 350 is better. In other words, the light emitting diode 300 of the present invention has better bonding strength, therefore having better bonding interface. Furthermore, the light emitting diode 300 of the present invention has better electricity characteristic.

### Second embodiment

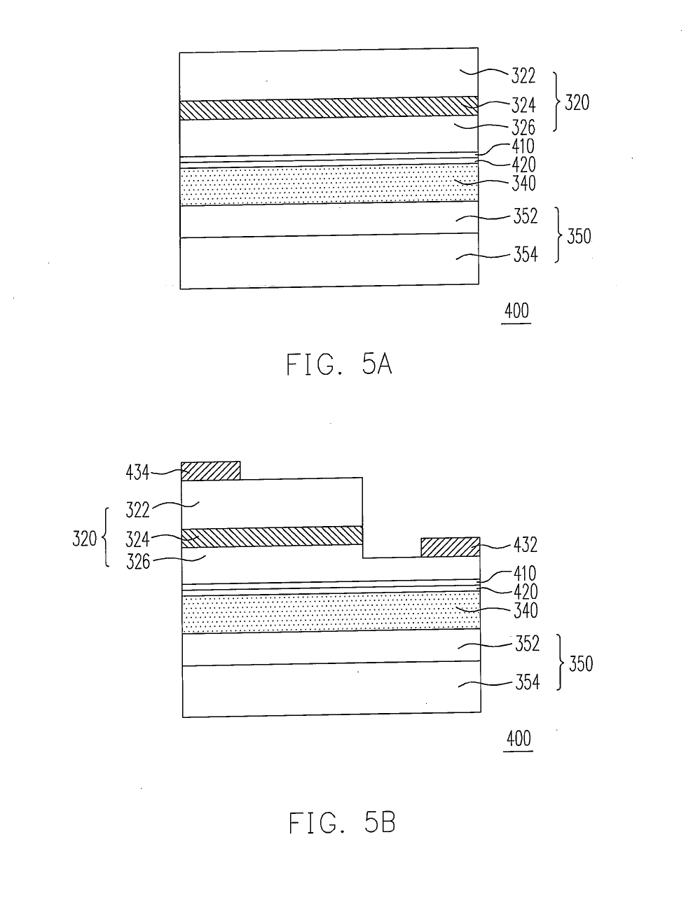

FIGS. 5A to 5B are schematic views of a process of manufacturing a light emitting diode according to a second embodiment of the present invention. As shown in FIG. 5A, the second embodiment is similar to the first embodiment, and the difference is that in the manufacturing method of the light emitting diode 400 of the second embodiment, in order to improve the interface characteristic between the gold layer 340 and the doped semiconductor layer 326, an ohmic contact layer 410 is formed on the doped semiconductor layer 326 after the doped semiconductor layer 326 is formed, for improving the interface electricity characteristic between the gold layer 340 and the doped semiconductor layer 326. For example, when the doped semiconductor layer 326 is a P-type doped semiconductor layer, the ohmic contact layer 410 is for example a nickel/gold layer. Further, in order to increase the light emitting efficiency, after the ohmic contact layer 410 is formed, a reflective layer can further be formed on the ohmic connect layer. The material of the reflective layer is for example aluminum or other suitable materials.

As shown in FIG. 5B, when manufacturing a planar light emitting diode, a part of the doped semiconductor layer 322 and the light emitting layer 324 are removed after the epitaxy substrate 310 is removed, for exposing a part of the surface of the doped semiconductor layer 326. Further, a bonding-pad 434 is formed on the doped semiconductor layer 322, and a bonding-pad 432 is formed on a part of the doped semiconductor layer 326 not covered by the light emitting layer 324, to finish the manufacturing process of the light emitting diode 400.

Note that the light emitting diode 300 of the first embodiment can be further manufactured as a planar light emitting diode as shown in FIG. 1, and the light emitting diode 400 of the second embodiment can be further manufactured as a upright light emitting diode as shown in FIG. 2.

In summary, the light emitting diode and the manufacturing method of the present invention have at least the following advantages:

Compared with the conventional technology, the present invention utilizes gold-germanium-silicon as the bonding materials. Because the gold-germanium-silicon ternary eutectic state is stable and the bonding strength is high, the light emitting diode of the present invention has higher bonding strength. Further, because the gold-germanium-silicon eutectic temperature is lower, during the high temperature laser lift-off manufacturing process, the thermal stress caused by thermal expansion can be decreased, so as to prevent the bonding strength between the gold layer and the bonding substrate from decreasing. Furthermore, the light emitting diode of the present invention has better electricity characteristic.

The light emitting diode manufacturing method of the present invention is compatible with the conventional manufacturing process, therefore additional manufacturing equipment is not needed for the light emitting diode manufacturing method of the present invention.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A light emitting diode manufacturing method, comprising:
forming a first-type doped semiconductor layer, a light emitting layer and a second-type doped semiconductor layer on an epitaxy substrate sequentially;
forming a gold layer on the second-type doped semiconductor layer;
providing a bonding substrate, wherein the bonding substrate comprises a silicon substrate and a germanium-contained layer disposed on the silicon substrate;
performing a bonding process on the germanium-contained layer of the bonding substrate and the gold layer; and
removing the epitaxy substrate.

2. The light emitting diode manufacturing method of claim 1, wherein the germanium-contained layer is a solid germanium layer or silicon germanium alloy layer.

3. The light emitting diode manufacturing method of claim 1, wherein a pressure applied in the bonding process is between 1 kg/cm2 to 100 kg/cm2.

4. The light emitting diode manufacturing method of claim 1, wherein a temperature applied in the bonding process is between 250° C. to 400° C.

5. The light emitting diode manufacturing method of claim 1, wherein the method of removing the epitaxy substrate comprises a laser lift-off process.

6. The light emitting diode manufacturing method of claim 5, wherein the laser lift-off process comprises a excimer laser process.

7. The light emitting diode manufacturing method of claim 1, further comprising performing a cleaning process to the bonding substrate, before performing the bonding process.

8. The light emitting diode manufacturing method of claim 1, further comprising forming a buffer layer on the epitaxy substrate, before forming the first-type doped semiconductor layer.

9. The light emitting diode manufacturing method of claim 8, further comprising removing the buffer layer, after removing the epitaxy substrate.

10. The light emitting diode manufacturing method of claim 1, further comprising forming an ohmic contact layer on the second-type doped semiconductor layer, before forming the gold layer.

11. The light emitting diode manufacturing method of claim 10, further comprising forming a reflective layer on the ohmic contact layer, after forming the ohmic contact layer.

12. The light emitting diode manufacturing method of claim 1, further comprising forming a bonding pad on the first-type doped semiconductor layer, after removing the epitaxy substrate.

13. The light emitting diode manufacturing method of claim 1, after removing the epitaxy substrate, the method further comprising:
removing a part of the first-type doped semiconductor layer and the light emitting layer, for exposing a part of the surface of the second-type doped semiconductor layer;
forming a first bonding pad on the first-type doped semiconductor layer; and
forming a second bonding pad on the second-type doped semiconductor layer not covered by the light emitting layer.
